(19) United States
(12) Patent Application Publication
(10) Pub. No.: US 2003/0077843 A1
(43) Pub. Date: Apr. 24, 2003

(54) Method of etching conductive layers for capacitor and semiconductor device fabrication

(75) Inventors: Hideyuki Yamauchi, Narita-shi (JP); Kouji Tsutsumi, Tateyama City (JP); Yohei Kawase, Sakura-shi (JP)

Correspondence Address: Patent Counsel, Applied Materials, Inc., P.O. Box 450A, Santa Clara, CA, 95052, US

(73) Assignee: Applied Materials, Inc.

(21) Appl. No.: 10/210,551

(22) Filed: Jul. 31, 2002

(30) Foreign Application Priority Data
Jul. 31, 2001 (JP) 2001-232521

(51) Int. Cl. H01L 21/00; H01L 21/8242; H01L 21/302; H01L 21/461

(52) U.S. Cl. 438/3; 438/240; 438/720; 438/722

(57) ABSTRACT

A method of etching a multi-layer film, wherein the multi-layer film comprises at least one conductive layer and a ferroelectric layer formed sequentially on a substrate comprises forming a hard mask on at least one of the at least one conductive layers. The hard mask is used to etch the first conductive layer and the ferroelectric layer at a temperature that may exceed 100 degrees. A semiconductor device comprises first electrodes formed on a substrate, ferroelectric portions formed on the first electrodes, second electrodes formed on the ferroelectric portions, and hard masks formed on the second electrode.

### CROSS-REFERENCE TO RELATED APPLICATIONS

This application claims priority to co-pending Japanese patent application number 2001-232521, filed in Japan on Jul. 31, 2001.

### BACKGROUND OF THE INVENTION

1. Field of the Invention

The present invention generally relates to a method of etching and, more particularly, to a method of etching conductive layers for use in both capacitors and in multi-layer ferroelectric films, as well as devices made therefrom.

2. Description of the Related Art

Precious metals such as ruthenium (Ru), platinum (Pt) and iridium (Ir) and conductive oxides such as ruthenium oxide (RuO₂) and iridium oxide (IrO₂) have been investigated as electrode materials for capacitors. For example, a capacitor having Ru electrodes is formed by sequentially forming a first Ru layer, a lead zirconate titanate (PZT) layer and a second Ru layer on a substrate. A resist mask having a predetermined pattern is formed on the second Ru layer, and the second Ru layer is etched. During the formation of the resist mask and during the etching of the second Ru layer, the substrate temperature is maintained at about 80 degrees. This is because subjecting the substrate to a temperature of, for example, 100 degrees or higher, would result in a deterioration of the resist, causing the resist to be unable to be removed after etching the second Ru layer. After the second Ru layer is etched as described above, the resist mask is removed. The PZT layer is usually etched at a temperature of 300 degrees, in order to obtain a sufficiently high etch rate. Since the resist would deteriorate at this temperature, the resist mask is removed prior to etching the PZT layer. After the resist mask is removed, the PZT layer is etched, using the patterned second Ru layer as a mask. After the etching of the PZT layer, the first Ru layer is etched while maintaining a substrate temperature of about 80 degrees. A capacitor comprising a Ru first electrode, a PZT layer, and a second Ru electrode is thereby formed.

As described above, the substrate temperature during the etching of the first and the second Ru layer is lower than the substrate temperature during the etching of the PZT layer. In order to form a capacitor having a first Ru electrode, a PZT layer, and a second Ru electrode, the substrate temperature must be adjusted significantly in order to etch each layer.

Furthermore, the Ru layers are typically etched at a comparatively low temperature of about 80 degrees, and the etching apparatus used for Ru layer etching is not compatible with the high temperature etching of PZT. Therefore, the PZT etch is performed in a second etch apparatus different from the etch apparatus used to etch the second Ru layer. After etching the PZT layer, the substrate is then removed and placed back in the first etch apparatus in order to etch the first Ru layer. As a result, the formation of a capacitor having the structure of an Ru electrode/PZT/Ru electrode is costly in terms of labor and time due to the required removal of the resist mask and the necessary changing of the etching apparatuses during the etching process.

Therefore, a need exists to provide a simplified etching process for etching a conductive layer and for etching a multi-layer film comprising a conductive layer and a ferroelectric layer.

### SUMMARY OF THE INVENTION

Embodiments of the present invention generally relate to the etching of conductive layers and the fabrication of multi-layer films comprising conductive layers and ferroelectric layers.

In one embodiment of the invention, an etching process for etching a multi-layer film, the multi-layer film comprising at least one conductive layer and a ferroelectric layer formed sequentially on a substrate comprises forming a hard mask on at least one of the at least one conductive layer. The hard mask is used to etch the conductive layer and the ferroelectric layer at a temperature that can exceed 100 degrees. The at least one conductive layer and the ferroelectric layer can be etched in succession.

A capacitor manufacturing process according to the present invention comprises forming a multi-layer film comprising a first conductive layer, a ferroelectric layer and a second conductive layer sequentially on a substrate. A hard mask is formed on the multi-layer film, and the hard mask is used to etch the first conductive layer, the ferroelectric layer and the second conductive layer at a temperature that may exceed 100 degrees, in order to form the capacitor.

A semiconductor device according to the present invention comprises first electrodes formed on a substrate, ferroelectric portions formed on the first electrodes, second electrodes formed on the ferroelectric portions, and hard masks formed on the second electrode. Each of the first and the second electrodes may comprise a precious metal or a conductive oxide. The ferroelectric portions may comprise a PZT-based ferroelectric that may exhibit hysteresis characteristics.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1a-1j are cross-sectional views of a substrate during various stages of processing according to one embodiment of the present invention;

FIG. 2 is a schematic diagram showing an exemplary plasma etching apparatus that may be used to practice embodiments of the invention described herein;

FIGS. 3a-3g are cross-sectional views of a substrate during various stages of substrate processing according to another embodiment of the invention;

FIG. 4 depicts a cross-sectional view of a ruthenium (Ru) layer that has been etched using an etching process according to an embodiment of the invention described herein;

FIG. 5 is a circuit diagram showing a semiconductor device comprising a capacitor formed by the etching process according to embodiments of the invention described herein; and

FIG. 6 is a graph depicting a hysteresis phenomenon of a ferroelectric material that may be etched using embodiments of the invention described herein.

### DETAILED DESCRIPTION

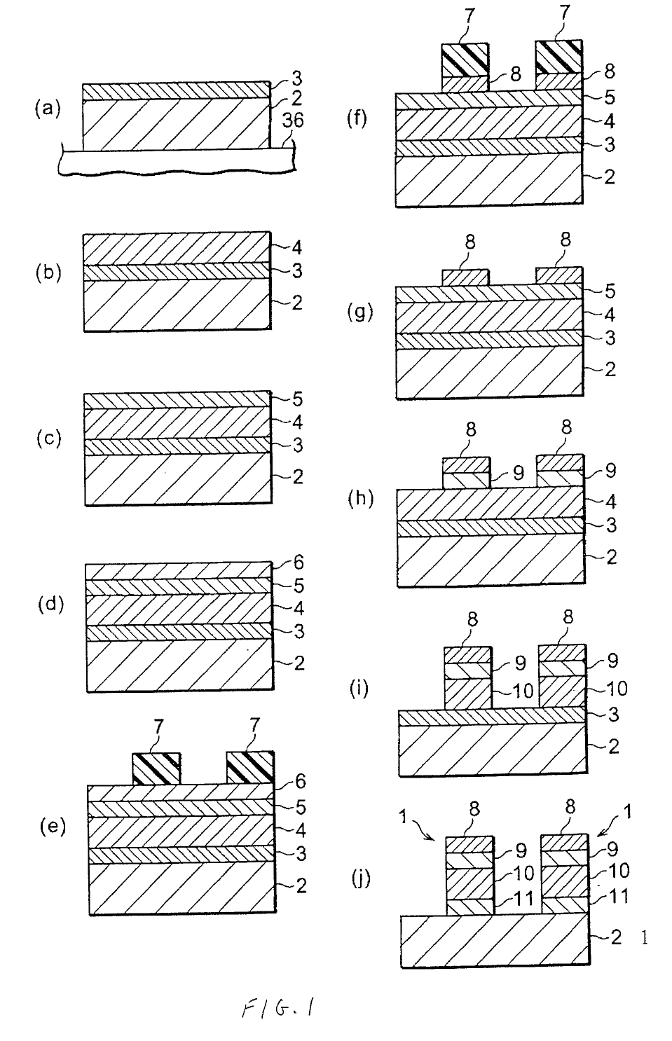

Embodiments described herein relate to an etching process. FIGS.1a-1j are cross-sectional views of a substrate during various stages of processing of a capacitor. The capacitor comprises first and second electrodes and a ferroelectric portion. The electrodes may comprise a precious metal as a conductive oxide. The ferroelectric portions may comprise a PZT-based ferroelectric that may exhibit hysteresis characteristics. The capacitor may comprise, for example, a first Ruthenium (Ru) electrode, a lead zirconate titanate, i.e., a PZT (PbZrₓTi₁₋ₓO_{3,<x<1}) dielectric, and a second Ru electrode.

The scope of the present invention is not limited to the embodiments discussed below. For example, while the conductive layers described herein as ruthenium (Ru) layers, other materials, including other precious metals such as platinum (Pt), iridium (Ir), and the like, as well as conductive oxides such as iridium oxide (IrO₂) may be used. Furthermore, while the ferroelectric layer is described herein as a PZT layer, the ferroelectric layer may include other elements such as lanthanum (La), niobium (Nb) and bismuth (Bi).

As shown in FIG. 1a, a first Ruthenium (Ru) layer 3 is formed on a surface of a substrate 2. The substrate 2 may be, for example, a silicon (Si) wafer, or a Si wafer having an insulating layer such as a silicon oxide (SiO₂) layer formed thereon. The substrate 2 may be a Si wafer upon which a partially completed semiconductor integrated circuit has been fabricated. The method employed for forming the first Ru layer 3 may be, for example, chemical vapor deposition (CVD) or physical vapor deposition (PVD). As shown in FIG. 1b, a PZT layer 4 is formed on the first Ru layer 3. The PZT layer 4 may be formed by a PVD process or a sol-gel process. Next, as shown in FIG. 1c, a second Ru layer 5 is formed on the PZT layer 4, using the same method as discussed above for forming the first Ru layer 3, with reference to FIG. 1a.

Subsequently, an SiO₂ layer 6 is formed on the second Ru layer 5, as shown in FIG. 1d. The SiO₂ layer 6 may be formed by, for example, a plasma CVD method using tetraethyl orthosilicate (TEOS) and oxygen (O₂) gas as raw materials. Thereafter, a resist layer (not shown) is applied on the SiO₂ layer 6, and the resist layer is exposed via a photomask (not shown) having a predetermined pattern. As shown in FIG. 1e, resist masks 7 are thereby formed. The resist masks 7 are then used to etch the SiO₂ layer 6, as shown in FIG. 1f. This etching may be performed using, for example, a plasma etching apparatus appropriate for SiO₂ layer etching. An etching gas, such as, for example, CF₄ and Cl₂, may be used to perform the SiO₂ layer etching. After etching the SiO₂ layer, the resist mask 7 is removed by ashing. As a result, hard masks 8 are formed as shown in FIG. 1g. The layer 6 that ultimately forms the hard masks 8 may also be fabricated of a silicon-based inorganic insulating material such as SiN, Si₃N₄, and SiON or a material such as titanium nitride (TiN).

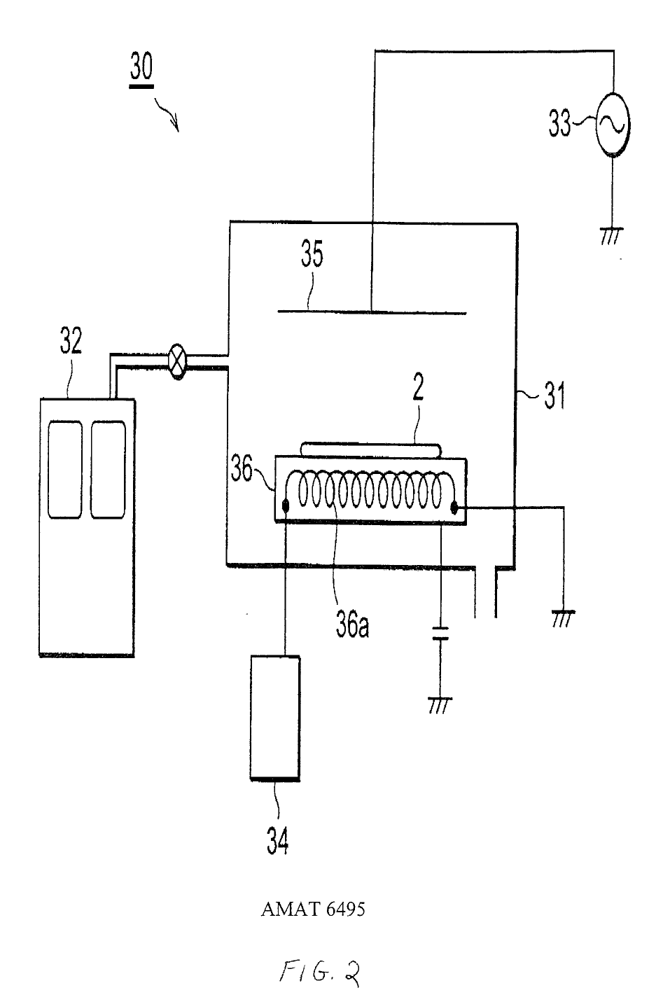

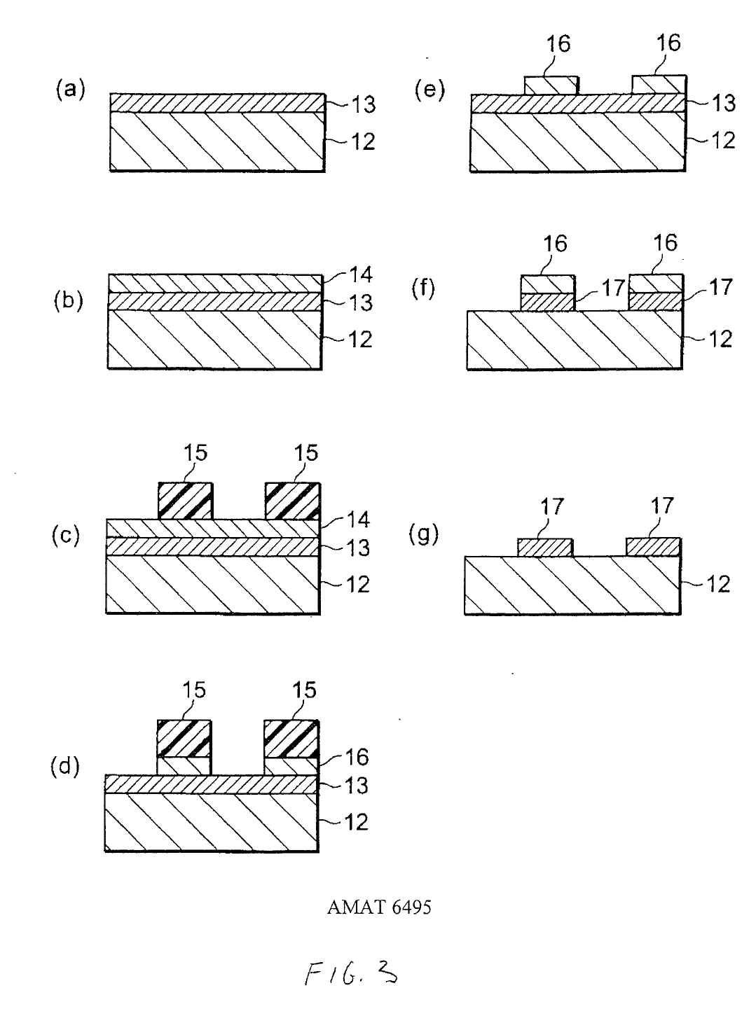

After the formation of the hard masks 8, the substrate 2 is placed in an etching chamber of a predetermined etching apparatus. The etching apparatus used here may be, for example, a plasma etching apparatus having a structure shown schematically in FIG. 2. As shown in FIG. 2, a plasma etching apparatus 30 comprises an etching chamber 31, a gas supply source 32, a high-frequency power source 33, a temperature regulator 34 and a gas exhausting system (not shown). An electrode 35 for supplying high-frequency power from the high frequency power source 33, and a substrate support 36 for carrying substrate 2 are disposed in the etching chamber 31. The substrate support 36 has, for example, a heater 36a disposed therein. The heater 36a is controlled by the temperature regulator 34, and the temperature of the substrate support 36 is thereby set to a predetermined temperature. The temperature of substrate 2 placed on the substrate support 36 is defined by the temperature of the substrate support 36. In the plasma etching apparatus 30, the temperature of the substrate support 36 can be raised to about 400 degrees.

After being placed on the substrate support 34, the substrate 2 is maintained at a predetermined temperature exceeding 100 degrees. The temperature of the substrate 2 is, for example, 250 degrees or higher. If the temperature of the substrate 2 is maintained lower than 250 degrees, the subsequent etching of the PZT layer 4 would have an etching rate that would be too low. Therefore, the temperature is set to 250 degrees or higher prior to the etching of the second Ru layer 5. Accordingly, after the etching of the second Ru layer 5, the temperature does not have to be changed, and the second Ru layer 5 and the PZT layer 4 may be etched at the same temperature. The temperature of the substrate 2 is, for example, 400 degrees or lower. If the temperature of the substrate 2 is higher than 400 degrees, the surfaces formed after the etching would be uneven.

In one embodiment of the invention, the temperature of the substrate 2 is maintained at 310 degrees. After the temperature of the substrate 2 becomes stable at 310 degrees, Cl₂ gas and O₂ gas are supplied into the etching chamber 31, and the etching of the second Ru layer 5 is performed using the hard masks 8. After the etching of the portions of the second Ru layer 5 that are not covered by the hard masks 8 is completed, the supply of Cl₂ gas and O₂ gas is terminated. Upper Ru electrodes 9 are thereby formed, as shown in FIG. 1h.

After the formation of the upper Ru electrodes 9, the PZT layer 4 is etched in the same etching chamber 31 and at substantially the same substrate temperature as the etching of the upper Ru electrodes 9. BCl₃ gas and Ar gas may be used to etch the PZT layer 4. BCl₃ gas and Ar gas are supplied into the etching chamber 31, and the PZT layer 4 is etched. The hard masks 8 as well as the upper Ru electrodes 9 protect portions of the PZT layer 4 from being etched, as shown in FIG. 1i. Process conditions useful for etching the PZT layer 4 are, for example, a flow rate of BCl₃ of 40 standard cubic centimeters per minute (sccm), a flow rate of Ar of 90 sccm, a chamber pressure of about 2.0 Pa (15 mTorr), a power output of for plasma generation of 1500W, a substrate bias output of 150W, and a substrate temperature of 310 degrees.

After the etching of the PZT layer 4 is completed, the supply of BCl₃ gas and Ar gas is terminated. As a result of the etching of the PZT layer 4, dielectric portions 10 are formed as shown in FIG. 1i. Next, Cl₂ gas and O₂ gas are supplied, and the first Ru layer 3 is etched under conditions that are substantially the same as those for the second Ru layer 5, thereby forming lower Ru electrodes 11. As a result of the etching process of the present invention, a capacitor 1, composed of Ru electrode/PZT/Ru electrode is formed, as shown in FIG. 1j. The capacitor 1 comprises the hard masks 8 formed on the lower Ru electrodes 11.

As described above, by using the hard masks 8, the first Ru layer 3, and the second Ru layer 5 can be etched at a temperature in a range from as low as 250 degrees to as high as 400 degrees. The PZT layer 4 can also be etched at a temperature in this temperature range. Therefore, the PZT layer 4 can be etched without changing the etching temperature after the second Ru layer 5 is etched. Similarly, the first Ru layer 3 can be etched without changing the etching temperature after etching the PZT layer 4.

Compared to the conventional method, the etching process of the present invention allows the Ru layers 3, 5 and the PZT layer 4 to be etched at substantially the same temperature. Also, to facilitate etching, the etching rate of the SiO₂ layer 6 can be made sufficiently lower compared to the etching rates of the Ru layers 3, 5 and the PZT layer 4. Furthermore, the etching of the Ru layers 3, 5 and the PZT layer 4 can be performed successively within the same etching chamber 31. Accordingly, no labor or time is spent to change the etching temperature or to transfer the substrate 2. Therefore, by using the present invention, the time required for etching is reduced and the process steps are simplified.

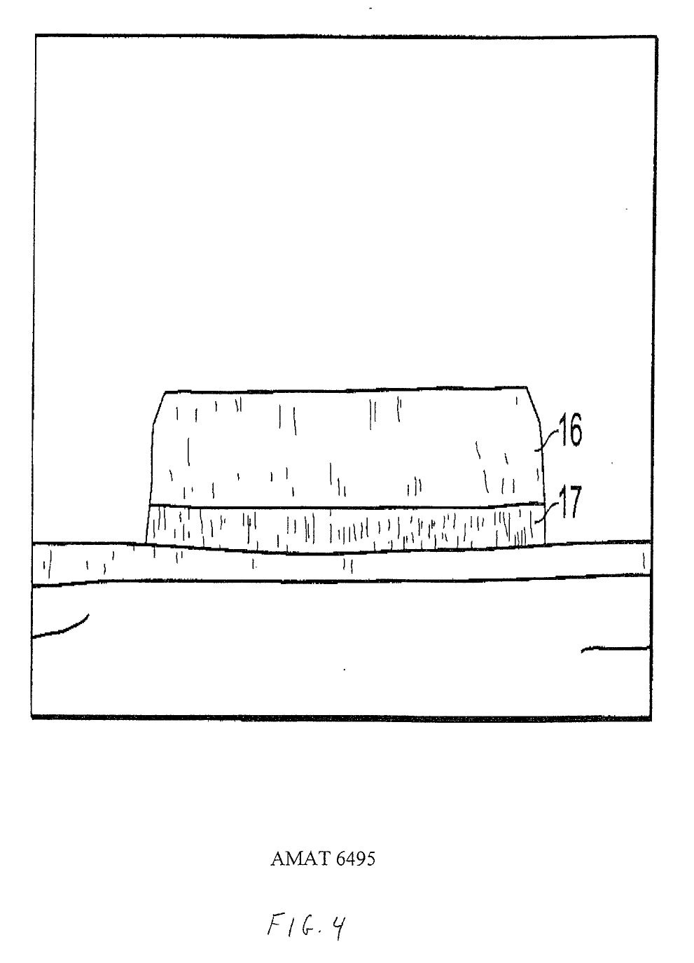

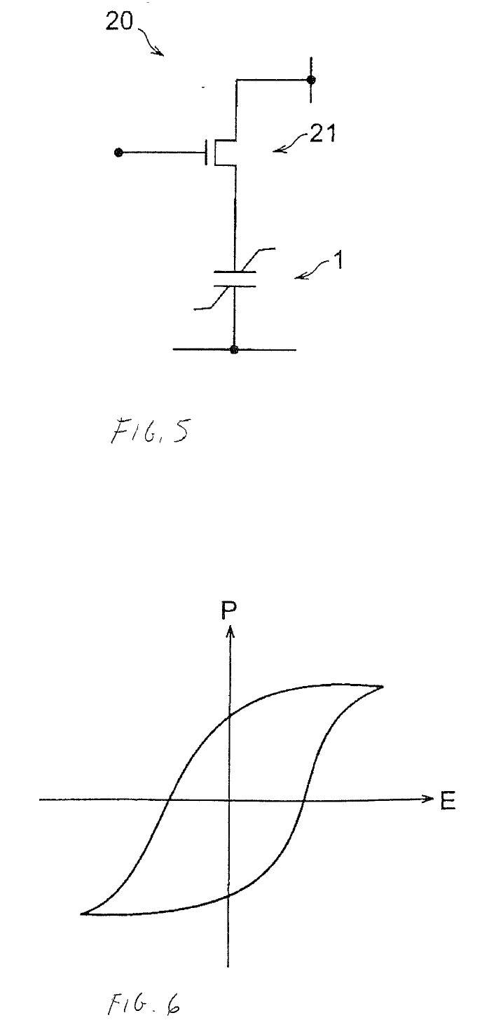

FIGS. 3a-3g are cross-sectional views of a substrate 12 during various stages of substrate processing according to another embodiment of the invention. As shown in FIG. 3a, a ruthenium (Ru) layer 13 is formed on a surface of the substrate 12. Here, the substrate 12 may be the same as the substrate 2 but is not limited thereto. Methods employed for forming the Ru layer 13 may be, for example, a chemical vapor deposition (CVD) method or sputtering. Next, an SiO₂ layer 14 is formed on the Ru layer 13, as shown in FIG. 3b. An illustrative method for forming the SiO₂ layer 14 is, for example, a plasma CVD method. After forming the SiO₂ layer 14, a resist layer (not shown) is applied on the SiO₂ layer 14, and the resist layer is exposed via a photomask (not shown) having a predetermined pattern. Resist masks 15 are formed, as indicated in FIG. 3c.

Next, the resist masks 15 are used to etch the SiO₂ layer 14. Thus, portions of the SiO₂ layer 14 that are not covered by the resist masks 15 are removed, as shown in FIG. 3d, using, for example, a plasma etching process. Etching gases, for example, CF₄ and Cl₂, may be used in the etching process. After this etching, the resist masks 15 are removed by ashing. As a result, hard masks 16 are formed as shown in FIG. 3e.

Thereafter, the Ru layer 13 is etched using the hard masks 16. Thus, portions of the Ru layer 13 that are covered by the hard masks 16 are not etched, as shown in FIG. 3f. Etching of the Ru layer 13 may be performed using, for example, a plasma etching method. In this case, the temperature of substrate 12 is set to a temperature exceeding 100 degrees. Etching of the Ru layer 13 may be performed using, for example, Cl₂ and O₂. After the etching is finished, the hard masks 8 are removed using hydrofluoric acid. According to the above-described steps, Ru electrodes 17 are formed, as indicated in FIG. 3g.

FIG. 4 depicts a schematic cross-sectional view of the Ru electrodes 17 that were etched using the patterned hard mask 16 using the etching process described with reference to FIGS. 3a-3g. The shape of the Ru electrode 17 is similar to the shape obtained using a conventional etching process using a resist mask.

Conventionally, a resist mask is formed on the Ru layer 13 in order to etch the Ru layer 13. In order to prevent the resist mask from deteriorating, the substrate temperature during the etching is between 30 degrees and 80 degrees. In the etching process described with reference to FIGS. 3a-3g, by using the hard masks 16 composed of SiO₂, the Ru layer 13 can be etched at a temperature between as low as 100 degrees and as high as 400 degrees. By using the etch method of the present invention, the range of process conditions available for forming the Ru electrode 17 is broader compared to the prior art. As a result, the method of the present invention provides for more flexibility in integrating the etch of the Ru electrode 17 with other process steps, such as steps before and after the formation of the Ru electrode 17. Overall, by using the method of present invention, the process steps can be simplified and the time for etching can be reduced.

FIG. 5 is a circuit diagram showing an example of a semiconductor device comprising the capacitor 1 formed using the etching process according to embodiments described herein. A semiconductor device 20 is composed of a field effect transistor (FET) 21 and the capacitor 1. The capacitor 1 comprises dielectric portions such as the dielectric portions 10 shown in FIG. 1i. The dielectric portions 10 may comprise PZT and may thereby exhibit hysteresis characteristics, as depicted in FIG. 6, thereby providing the device 20 with a memory effect. In FIG. 6, the abscissa represents an applied electric field and the ordinate represents polarization.

The etching process of the present is beneficial in that the process steps are simplified. Furthermore, a semiconductor device manufacturing process that includes the etching method of the present invention is simplified and process time is reduced. Devices manufactured using the method of the present invention are advantageous in that the cost of manufacture is lower than devices that are formed using conventional etch processes.

While the foregoing is directed to embodiments of the present invention, other and further embodiments of the invention may be devised without departing from the basic scope thereof, and the scope thereof is determined by the claims that follow.

1. A method of etching a multi-layer film comprising at least one conductive layer and a ferroelectric layer, wherein the method comprises:
forming a hard mask layer on one of the at least one conductive layer; and
using the hard mask to etch the at least one conductive layer and the ferroelectric layer.

2. The method of claim 1 wherein the hard mask comprises a material selected from the group consisting of a silicon-based inorganic material and titanium nitride.

3. The method of claim 1 wherein the ferroelectric layer comprises lead zirconate titanate (PZT).

4. The method of claim 1 wherein the ferroelectric layer comprises an element selected from the group consisting of lanthanum (La), niobium (Nb) and bismuth (Bi).

5. The method of claim 1 wherein the at least one conductive layer comprises a material selected from the group consisting of precious metals and conductive oxides.

6. The method of claim 5 wherein the at least one conductive layer comprises a material selected from the group consisting of ruthenium (Ru), iridium (Ir), platinum (Pt), and iridium oxide (IrO2).

7. The method of claim 1 wherein the etching of the at least one conductive layer is performed at a temperature greater than 100 degrees.

8. The method of claim 7 wherein the etching of the at least one conductive layer is performed at a temperature in a range between 250 degrees and 400 degrees.

9. The method of claim 1 wherein the hard mask is used to etch a first conductive layer, a second conductive layer, and a ferroelectric layer formed between the first conductive layer and the second conductive layer.

10. The method of claim 1 wherein the etching is performed in a single etching chamber.

11. A method of etching a multi-layer film comprising at least one conductive layer and a ferroelectric layer, wherein the method comprises:
forming a hard mask on one of the at least one conductive layer, wherein the at least one conductive layer comprises a material selected from the group consisting of precious metals and conductive oxides; and
using the hard mask to etch selected portions of the at least one conductive layer and the ferroelectric layer, wherein the etching is performed at a temperature in a range of 250 degrees to 400 degrees, and wherein the etching is performed in a single etching chamber.

12. A method of etching a multi-layer film comprising a first conductive layer, a second conductive layer, and a ferroelectric layer formed between the first conductive layer and the second conductive layer, wherein the method comprises:
forming a hard mask on the second conductive layer, wherein the hard mask comprises a material selected from the group consisting of silicon-based inorganic materials and titanium nitride, and wherein the first conductive layer and the second conductive layers comprise a material selected from the group consisting of ruthenium (Ru), iridium (Ir), platinum (Pt), and iridium oxide (IrO2); and
using the hard mask to etch selected portions of the first conductive layer, portions of the second conductive layer, and the ferroelectric layer, wherein the etching is performed at a temperature in a range of 250 degrees to 400 degrees, and wherein the etching is performed in a single etching chamber.

13. A method of forming a capacitor, comprising the steps of:
forming a multi-layer film comprising a first conductive layer, a ferroelectric layer and a second conductive layer sequentially on a substrate;
forming a hard mask on the multi-layer film; and
using the hard mask to etch the first conductive layer, the ferroelectric layer and the second conductive layer.

14. The method of claim 13 wherein the hard mask is formed on the second conductive layer.

15. The method of claim 13 wherein the hard mask comprises a material selected from the group consisting of silicon-based inorganic materials and titanium nitride.

16. The method of claim 13 wherein the ferroelectric layer comprises lead zirconate titanate (PZT).

17. The method of claim 13 wherein the ferroelectric layer comprises an element selected from the group consisting of lanthanum (La), niobium (Nb) and bismuth (Bi).

18. The method of claim 13 wherein a layer selected from the group consisting of the first conductive layer and the second conductive layer comprises a material selected from the group consisting of precious metals and conductive oxides.

19. The method of claim 18 wherein a layer selected from the group consisting of the first conductive layer and the second conductive layer comprises a material selected from the group consisting of ruthenium (Ru), iridium (Ir), platinum (Pt), and iridium oxide (IrO2).

20. The method of claim 13 wherein the etching of the first conductive layer, the ferroelectric layer and the second conductive layer is performed at a temperature greater than 100 degrees.

21.The method of claim 13 wherein the etching of the first conductive layer, the ferroelectric layer and the second conductive layer is performed at a temperature in a range between 250 degrees and 400 degrees.

22. A method of forming a capacitor, comprising the steps of:
forming a multi-layer film comprising a first conductive layer, a ferroelectric layer and a second conductive layer sequentially on a substrate;
forming a hard mask on the second conductive layer, wherein the hard mask comprises a material selected from the group consisting of silicon-based inorganic materials and titanium nitride, and wherein the first conductive layer and the second conductive layers comprise a material selected from the group consisting of precious metals and conductive oxides; and
using the hard mask to etch the first conductive layer, the ferroelectric layer and the second conductive layer, wherein the etching is performed at a temperature in a range of 250 degrees to 400 degrees, and wherein the etching is performed in a single etching chamber.

23. A semiconductor device comprising:
first electrodes formed on a substrate;
ferroelectric portions formed on said first electrodes;
second electrodes formed on said ferroelectric portions; and
a hard mask formed on the second electrodes.

24. The semiconductor device of claim 23, wherein the first electrodes and the second electrodes comprise a material selected from the group consisting of precious metals and a conductive oxides.

25. The semiconductor device of claim 23 wherein the ferroelectric portions comprise lead zirconate titanate.

26. The semiconductor device of claim 23 wherein the hard mask comprises a material selected from the group consisting of silicon-based inorganic materials and titanium nitride.

27. A semiconductor device comprising:
first electrodes formed on a substrate, wherein the first electrodes comprise a material selected from the group consisting of precious metals and a conductive oxides;
ferroelectric portions formed on said first electrodes, wherein the ferroelectric portions comprise lead zirconate titanate;
second electrodes formed on said ferroelectric portions wherein the second electrodes comprise a material selected from the group consisting of precious metals and a conductive oxides; and
a hard mask formed on the second electrodes.
